(19) United States
(12) Patent Application Publication
(10) Pub. No.: US 2016/0096729 A1
(43) Pub. Date: Apr. 7, 2016

(54) Photolithography Structures and Methods

(71) Applicant: Pixtronix, Inc., San Diego, CA (US)

(72) Inventors: Javier Villarreal, Somerville, MA (US); Timothy Brosnihan, Natick, MA (US); Chin-Yuan Ho, Zhudong Township (TW); Hung-Chien Lin, Zhubei City (TW)

(21) Appl. No.: 14/508,342

(22) Filed: Oct. 7, 2014

(51) Int. Cl. B81C 1/00; B81B 7/02; G06T 1/20; B81B 3/00

(52) U.S. Cl. CPC B81C 1/00523; B81B 3/0029; B81B 7/02; B81C 1/0019; B81C 1/00412; G06T 1/20; B81B 2203/0307; B81C 2201/0159; B81C 2201/0105

(57) ABSTRACT

This disclosure provides systems, methods and apparatus including processes that use two layers of resist, with a layer of etch stop material in between. The two layers of resist may be etched in separate processes to form devices having vias with sidewalls that extend through both layers of resist

### TECHNICAL FIELD

This disclosure relates to electromechanical systems having features formed from thin films deposited onto sidewalls of molds, including beams having high aspect ratios, and to devices formed through photolithography and other methods for forming such features.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

Certain MEMS devices, including certain MEMS displays, require the creation of almost 90 degree sidewalls in a layer of photoresist during a photolithography process. The creation of 90 degree sidewalls in the layer of photoresist currently requires precise photo-lithography and thick layers of expensive specialty photoresist. Additionally, the process for patterning the thick layer of specialty photoresist requires long photo exposure time, tight control over the exposure, pre or post exposure bakes, and ultraviolet (UV) exposure.

Although existing technologies for forming features having high aspect ratios can work well, there remains a need for improved structures and processes for forming MEMS devices.

### SUMMARY

The systems, methods and devices of this disclosure each have several innovative aspects, no single one of which is solely responsible for the desirable attributes disclosed herein.

One innovative aspect of the subject matter described in this disclosure can be implemented in a method for manufacturing a microelectromechancial device. The method may include depositing on a substrate, a first layer of resist material, a layer of etch stop material resistant to a first etch process, and a second layer of the resist material. The method etches the second layer of resist material using a first etch process to form a first pattern within the second layer of resist material. The method applies a mask to the patterned layer of resist material. The mask has gaps that expose a portion of the etch stop layer. The method etches, with a second process, the etch stop layer and the first resist layer to form a mold having features that extend through the first and the second layer of resist material.

In some implementations, the systems, devices, and methods described herein include methods for manufacturing an electromechancial system (EMS) device. The methods may include depositing on a substrate, a first layer of sacrificial material, a layer of etch stop material resistant to a first etch process, and a second layer of the sacrificial material. The method may include etching the second layer of sacrificial material using the first etch process to form a first pattern within the second layer of sacrificial material, applying a mask to the patterned layer of sacrificial material that exposes at least a portion of the etch stop material, and etching with a second etch process the etch stop material and the first layer of sacrificial material to form a mold having features that extend through the first and second layers of sacrificial material. In some implementations, the methods also include selecting the thickness of the second layer of sacrificial material to select a feature size of a component in the EMS device. In some implementations the methods include depositing the first layer of sacrificial material and the second layer of sacrificial material includes depositing layers of between 1 and 10 μm (microns). In some implementations, depositing at least one of the first and second layers of sacrificial material includes depositing a layer of resist material. Depositing the layer of etch stop material may include depositing a layer of material between about 25 and 5000 Å (angstroms) and may include depositing a layer of material selected from the group consisting of amorphous silicon, Titanium, silicon oxide, silicon carbide, and silicon nitride.

In some implementations, applying the mask includes applying a hard mask and may include sputtering a pattern of material selected from the group consisting of metals, silicon dioxide, and geranium.

In some implementations, etching using the first etch process includes anisotropic etching with oxygen ions and in some implementations etching with the second process includes anisotropic etching with oxygen. Etching with a first process may also include anisotropic etching to form a sidewall substantially perpendicular to the substrate.

In some implementations, the methods may also include depositing a layer of semiconductor material over the etched first and second layers of sacrificial material to form features of the EMS device and removing the first and second layers of sacrificial material and etch stop layer to release the features for use within the EMS device. Removing the first and second layers of sacrificial material and etch stop layer may include etching with a fluorine compound and oxygen.

In another aspect, the systems, methods and devices described herein may include an electromechanical system (EMS) device that has a substrate with a first surface, an anchor attached to the first surface and having a sidewall with a first portion and a second portion, and a junction joining the first portion with the second portion, and wherein the first portion is in contact with the first surface of the substrate and the second portion of the sidewall is spaced away from the first surface. The device may, in some implementations also include a beam connected to the second portion of the sidewall and extending substantially parallel to the first surface of the substrate. The beam may include elements movable between a first position and a second position.

In some implementations, the substrate includes a transparent material and in some implementations the anchor has a height between 2 and 20 μm (microns).

In some implementations, the first portion of the sidewall of the EMS device has a first inclination relative to the first surface of the substrate and the second portion of the sidewall has a second, different inclination relative to the first surface of the substrate. In some other implementations the first portion of the sidewall and the second portion of the sidewall are inclined substantially orthogonally relative to the first surface of the substrate.

The anchor may include a second sidewall having a first portion and second portion and a junction joining the first portion with the second portion and the junction may include a coupling of semiconductor material having a first end joined to the first portion of the sidewall and a second end being laterally spaced from the first end and joined to the second portion of the sidewall.

In some implementations, the substrate includes a plurality of anchors and a plurality beams having movable elements for modulating light to provide a display, a processor capable of communicating with the display, the processor being capable of processing image data and a memory device capable of communicating with the processor. Some implementations may also include a driver circuit capable of sending at least one signal to the display and a controller capable of sending at least a portion of the image data to the driver circuit. An image source module may be included that is capable of sending the image data to the processor, wherein the image source module includes at least one of a receiver, transceiver, and transmitter. An input device may be included that is capable of receiving input data and communicating the input data to the processor.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1A shows a schematic diagram of an example direct-view microelectromechanical systems (MEMS)-based display apparatus.

FIG. 1B shows a block diagram of an example host device.

FIGS. 2A and 2B show views of an example dual actuator shutter assembly.

FIG. 3 shows an example MEMS shutter assembly formed on a substrate.

FIG. 4 shows a cross-sectional view of an example substrate having a resist coating.

FIG. 5 shows one example of an etch stop layer.

FIG. 6 shows an example of a mold layer applied to the etch stop of FIG. 5.

FIG. 7 shows an example of a deposition pattern mold hard mask.

FIGS. 8 shows an example of a resist etched by an etching process.

FIG. 9 shows an example of a deposition of a hard mask.

FIGS. 10A and 10B show an example of a via formed through two layers of resist.

FIG. 10C and 10D show a cross-sectional view of another example a via formed through two layers of resist.

FIGS. 11A and 11B show a cross-sectional view of an example of components of a shutter assembly.

FIG. 12 is a flow chart diagram of one process for forming a MEMS device.

FIGS. 13A and 13B show system block diagrams of an example display device that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that is capable of displaying an image, whether in motion (such as video) or stationary (such as still images), and whether textual, graphical or pictorial. The concepts and examples provided in this disclosure may be applicable to a variety of displays, such as liquid crystal displays (LCDs), organic light-emitting diode (OLED) displays, field emission displays, and electromechanical systems (EMS) and microelectromechanical (MEMS)-based displays, in addition to displays incorporating features from one or more display technologies.

The described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, wearable devices, clocks, calculators, television monitors, flat panel displays, electronic reading devices (such as e-readers), computer monitors, auto displays (such as odometer and speedometer displays), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, in addition to non-EMS applications), aesthetic structures (such as display of images on a piece of jewelry or clothing) and a variety of EMS devices.

The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

The devices, systems and methods described herein, in one aspect, include processes that can form the components of a MEMS device. In one implementation, the processes form a mold that can support the deposition of semiconductor materials that can be patterned and formed to create the individual components of a MEMS device, such as a light modulator. For example, molds may have plateaus that can support the deposition of a semiconductor material, such as amorphous silicon. The amorphous silicon may be laid on the plateau as a substantially thin film. The deposited thin film may be hardened and the mold supporting that thin film may be etched, washed, or otherwise removed to the leave the thin film in place to act as the shutter, or some other component of the MEMS device. Some components of the MEMS device are movable, and to that end are held above or suspended over the surface of the MEMS substrate. To achieve this, the MEMS device may include posts or anchors that are formed on the surface of the substrate and extend away from the substrate. The posts are secured to the substrate at one end, and at another end the posts are connected to movable elements that are held away from the surface of the substrate. The systems and processes described herein build these posts or anchors using processes that build molds to form the movable components and subsequently build the mold for the posts or anchors that will provide a stable and secure attachment for the components. In some implementations, the process uses two layers of resist, with a layer of sacrificial etch stop material in between. The mold for the movable components is formed from the exposed layer of resist, and then the sacrificial etch stop layer is removed, at least in part, to expose the other layer of resist. This other layer of resist is shaped to form a mold. This mold uses the substrate as a bottom wall, thereby forming a via that extends through both layers of resist. In some implementations, the bottom wall is the substrate, such as a glass or silicon substrate, and the bottom wall is the surface of that glass or silicon substrate. But in other implementations, the bottom wall may be the substrate with a layer or layers of material laid over the substrate, such as a diffusion layer or a metallization layer. In any of these implementations, these vias can form the mold for the posts or anchors.

In some implementations, the processes and devices have vias that extend through two layers of resist separated by a layer of etch stop. The two layers of resist may be etched in separate processes thereby reducing the need for specialty photoresists that can allow for the formation of deep vias with sidewalls that are substantially perpendicular to the substrate.

Particular implementations of the subject matter described in this disclosure can be implemented to realize one or more of the following potential advantages. In one aspect, the two-step process of forming the vias through the layers of resist can more quickly form the via by avoiding the use of photoresists that require long exposure time to provide etch depths comparable to the thickness of the two layers of resist.

In another aspect, the processes described herein divide the resist etch process into two steps and can use a conventional photoresist for the molds. Typically, the conventional photoresists can tolerate higher processing temperatures than the specialty resists, and in particular, conventional resists shrink less and morphologically change less when heated than specialty resists. The ability to use higher temperatures allows for higher temperature baking and higher temperatures for depositing materials, such as amorphous silicon, silicon carbide, diamond, and low temperature oxides (LTO).

In some implementations, the systems and methods described herein allow for the use of thin layers of conventional resist materials and can improve processing times for patterning mold sidewalls through lithography. Additionally, the systems and methods described herein may reduce the need for specialty exposure tools and may allow lithography with stepper or scanner technology and provide high throughput. Further, thinner resist layers may allow for reducing the minimum critical dimension for the mold.

Additionally, in some implementations, the two step process may allow a combination of anisotropic etch process for one resist layer and an isotropic etch for another resist layer and may be used to make sidewalls that have an incline relative to the substrate and are disposed at an angle other than 90 degrees.

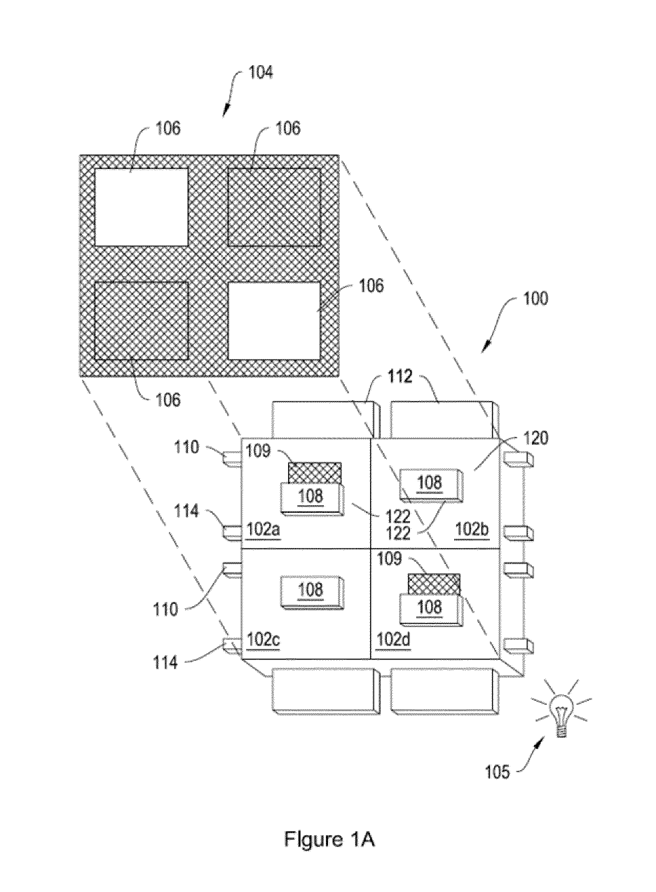

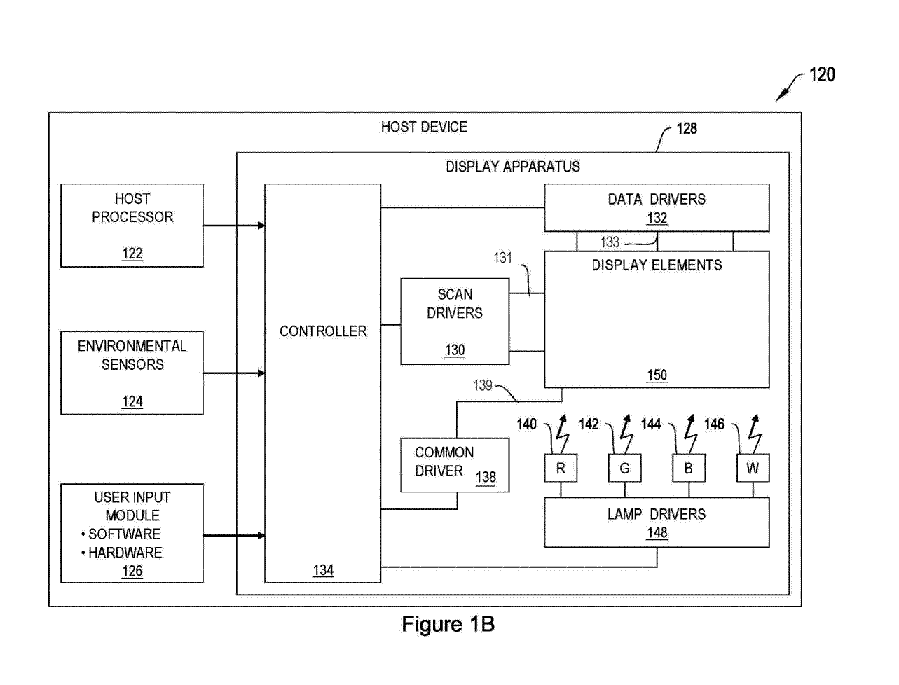

FIG. 1A shows a schematic diagram of an example direct-view MEMS-based display apparatus 100. The display apparatus 100 includes a plurality of light modulators 102a-102d (generally light modulators 102) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide a luminance level in an image 104. With respect to an image, a pixel corresponds to the smallest picture element defined by the resolution of image. With respect to structural components of the display apparatus 100, the term pixel refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the image can be seen by looking directly at the display apparatus, which contains the light modulators and optionally a backlight or front light for enhancing brightness and/or contrast seen on the display.

Direct-view displays may operate in either a transmissive or reflective mode. In a transmissive display, the light modulators filter or selectively block light which originates from a lamp or lamps positioned behind the display. The light from the lamps is optionally injected into a lightguide or backlight so that each pixel can be uniformly illuminated. Transmissive direct-view displays are often built onto transparent substrates to facilitate a sandwich assembly arrangement where one substrate, containing the light modulators, is positioned over the backlight. In some implementations, the transparent substrate can be a glass substrate (sometimes referred to as a glass plate or panel), or a plastic substrate. The glass substrate may be or include, for example, a borosilicate glass, wine glass, fused silica, a soda lime glass, quartz, artificial quartz, Pyrex, or other suitable glass material.

Each light modulator 102 can include a shutter 108 and an aperture 109. To illuminate a pixel 106 in the image 104, the shutter 108 is positioned such that it allows light to pass through the aperture 109. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix coupled to the substrate and to the light modulators for controlling the movement of the shutters. The control matrix includes a series of electrical interconnects (such as interconnects 110, 112 and 114), including at least one write-enable interconnect 110 (also referred to as a scan line interconnect) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the write-enabling voltage, V_{WE}), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate drive voltages, which are typically higher in magnitude than the data voltages, to the light modulators 102. The application of these drive voltages results in the electrostatic driven movement of the shutters 108.

The control matrix also may include, without limitation, circuitry, such as a transistor and a capacitor associated with each shutter assembly. In some implementations, the gate of each transistor can be electrically connected to a scan line interconnect. In some implementations, the source of each transistor can be electrically connected to a corresponding data interconnect. In some implementations, the drain of each transistor may be electrically connected in parallel to an electrode of a corresponding capacitor and to an electrode of a corresponding actuator. In some implementations, the other electrode of the capacitor and the actuator associated with each shutter assembly may be connected to a common or ground potential. In some other implementations, the transistor can be replaced with a semiconducting diode, or a metal-insulator-metal switching element.

FIG. 1B shows a block diagram of an example host device 120 (i.e., cell phone, smart phone, PDA, MP3 player, tablet, e-reader, netbook, notebook, watch, wearable device, laptop, television, or other electronic device). The host device 120 includes a display apparatus 128 (such as the display apparatus 100 shown in FIG. 1A), a host processor 122, environmental sensors 124, a user input module 126, and a power source.

The display apparatus 128 includes a plurality of scan drivers 130 (also referred to as write enabling voltage sources), a plurality of data drivers 132 (also referred to as data voltage sources), a controller 134, common drivers 138, lamps 140-146, lamp drivers 148, an array of display elements 150, such as the light modulators 102 shown in FIG. 1A. The scan drivers 130 apply write enabling voltages to scan line interconnects 131. The data drivers 132 apply data voltages to the data interconnects 133.

In some implementations of the display apparatus, the data drivers 132 are capable of providing analog data voltages to the array of display elements 150, especially where the luminance level of the image is to be derived in analog fashion. In analog operation, the display elements are designed such that when a range of intermediate voltages is applied through the data interconnects 133, there results a range of intermediate illumination states or luminance levels in the resulting image. In some other implementations, the data drivers 132 are capable of applying only a reduced set, such as 2, 3 or 4, of digital voltage levels to the data interconnects 133. In implementations in which the display elements are shutter-based light modulators, such as the light modulators 102 shown in FIG. 1A, these voltage levels are designed to set, in digital fashion, an open state, a closed state, or other discrete state to each of the shutters 108. In some implementations, the drivers are capable of switching between analog and digital modes.

The scan drivers 130 and the data drivers 132 are connected to a digital controller circuit 134 (also referred to as the controller 134). The controller 134 sends data to the data drivers 132 in a mostly serial fashion, organized in sequences, which in some implementations may be predetermined, grouped by rows and by image frames. The data drivers 132 can include series-to-parallel data converters, level-shifting, and for some applications digital-to-analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 139. In some other implementations, the common drivers 138, following commands from the controller 134, issue voltage pulses or signals to the array of display elements 150, for instance global actuation pulses which are capable of driving and/or initiating simultaneous actuation of all display elements in multiple rows and columns of the array.

Each of the drivers (such as scan drivers 130, data drivers 132 and common drivers 138) for different display functions can be time-synchronized by the controller 134. Timing commands from the controller 134 coordinate the illumination of red, green, blue and white lamps (140, 142, 144 and 146 respectively) via lamp drivers 148, the write-enabling and sequencing of specific rows within the array of display elements 150, the output of voltages from the data drivers 132, and the output of voltages that provide for display element actuation. In some implementations, the lamps are light emitting diodes (LEDs).

The controller 134 determines the sequencing or addressing scheme by which each of the display elements can be re-set to the illumination levels appropriate to a new image 104. New images 104 can be set at periodic intervals. For instance, for video displays, color images or frames of video are refreshed at frequencies ranging from 10 to 300 Hertz (Hz). In some implementations, the setting of an image frame to the array of display elements 150 is synchronized with the illumination of the lamps 140, 142, 144 and 146 such that alternate image frames are illuminated with an alternating series of colors, such as red, green, blue and white. The image frames for each respective color are referred to as color subframes. In this method, referred to as the field sequential color method, if the color subframes are alternated at frequencies in excess of 20 Hz, the human visual system (HVS) will average the alternating frame images into the perception of an image having a broad and continuous range of colors. In some other implementations, the lamps can employ primary colors other than red, green, blue and white. In some implementations, fewer than four, or more than four lamps with primary colors can be employed in the display apparatus 128.

In some implementations, where the display apparatus 128 is designed for the digital switching of shutters, such as the shutters 108 shown in FIG. 1A, between open and closed states, the controller 134 forms an image by the method of time division gray scale. In some other implementations, the display apparatus 128 can provide gray scale through the use of multiple display elements per pixel.

In some implementations, the data for an image state is loaded by the controller 134 to the array of display elements 150 by a sequential addressing of individual rows, also referred to as scan lines. For each row or scan line in the sequence, the scan driver 130 applies a write-enable voltage to the write enable interconnect 131 for that row of the array of display elements 150, and subsequently the data driver 132 supplies data voltages, corresponding to desired shutter states, for each column in the selected row of the array. This addressing process can repeat until data has been loaded for all rows in the array of display elements 150. In some implementations, the sequence of selected rows for data loading is linear, proceeding from top to bottom in the array of display elements 150. In some other implementations, the sequence of selected rows is pseudo-randomized, in order to mitigate potential visual artifacts. And in some other implementations, the sequencing is organized by blocks, where, for a block, the data for only a certain fraction of the image is loaded to the array of display elements 150. For example, the sequence can be implemented to address only every fifth row of the array of the display elements 150 in sequence.

In some implementations, the addressing process for loading image data to the array of display elements 150 is separated in time from the process of actuating the display elements. In such an implementation, the array of display elements 150 may include data memory elements for each display element, and the control matrix may include a global actuation interconnect for carrying trigger signals, from the common driver 138, to initiate simultaneous actuation of the display elements according to data stored in the memory elements.

In some implementations, the array of display elements 150 and the control matrix that controls the display elements may be arranged in configurations other than rectangular rows and columns. For example, the display elements can be arranged in hexagonal arrays or curvilinear rows and columns.

The host processor 122 generally controls the operations of the host device 120. For example, the host processor 122 may be a general or special purpose processor for controlling a portable electronic device. With respect to the display apparatus 128, included within the host device 120, the host processor 122 outputs image data as well as additional data about the host device 120. Such information may include data from environmental sensors 124, such as ambient light or temperature; information about the host device 120, including, for example, an operating mode of the host or the amount of power remaining in the host device's power source; information about the content of the image data; information about the type of image data; and/or instructions for the display apparatus 128 for use in selecting an imaging mode.

In some implementations, the user input module 126 enables the conveyance of personal preferences of a user to the controller 134, either directly, or via the host processor 122. In some implementations, the user input module 126 is controlled by software in which a user inputs personal preferences, for example, color, contrast, power, brightness, content, and other display settings and parameters preferences. In some other implementations, the user input module 126 is controlled by hardware in which a user inputs personal preferences. In some implementations, the user may input these preferences via voice commands, one or more buttons, switches or dials, or with touch-capability. The plurality of data inputs to the controller 134 direct the controller to provide data to the various drivers 130, 132, 138 and 148 which correspond to optimal imaging characteristics.

The environmental sensor module 124 also can be included as part of the host device 120. The environmental sensor module 124 can be capable of receiving data about the ambient environment, such as temperature and or ambient lighting conditions. The sensor module 124 can be programmed, for example, to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

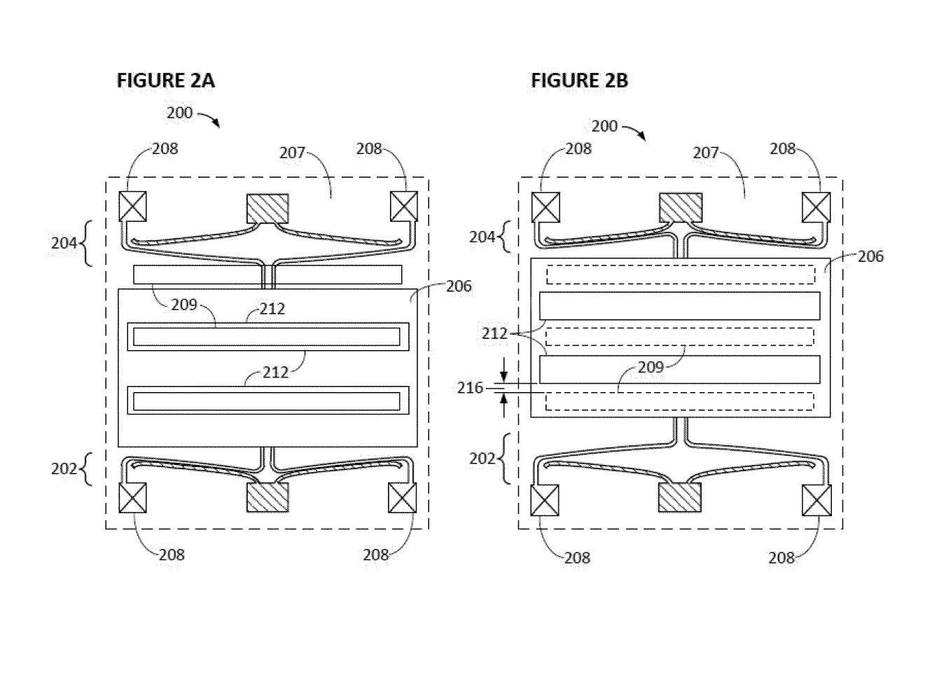

FIGS. 2A and 2B show views of an example dual actuator shutter assembly 200. The dual actuator shutter assembly 200, as depicted in FIG. 2A, is in an open state. FIG. 2B shows the dual actuator shutter assembly 200 in a closed state. The shutter assembly 200 includes actuators 202 and 204 on either side of a shutter 206. Each actuator 202 and 204 is independently controlled. A first actuator, a shutter-open actuator 202, serves to open the shutter 206. A second opposing actuator, the shutter-close actuator 204, serves to close the shutter 206. Each of the actuators 202 and 204 can be implemented as compliant beam electrode actuators. The actuators 202 and 204 open and close the shutter 206 by driving the shutter 206 substantially in a plane parallel to an aperture layer 207 over which the shutter is suspended. The shutter 206 is suspended a short distance over the aperture layer 207 by anchors 208 attached to the actuators 202 and 204. Having the actuators 202 and 204 attach to opposing ends of the shutter 206 along its axis of movement reduces out of plane motion of the shutter 206 and confines the motion substantially to a plane parallel to the substrate (not depicted).

In the depicted implementation, the shutter 206 includes two shutter apertures 212 through which light can pass. The aperture layer 207 includes a set of three apertures 209. In FIG. 2A, the shutter assembly 200 is in the open state and, as such, the shutter-open actuator 202 has been actuated, the shutter-close actuator 204 is in its relaxed position, and the centerlines of the shutter apertures 212 coincide with the centerlines of two of the aperture layer apertures 209. In FIG. 2B, the shutter assembly 200 has been moved to the closed state and, as such, the shutter-open actuator 202 is in its relaxed position, the shutter-close actuator 204 has been actuated, and the light blocking portions of the shutter 206 are now in position to block transmission of light through the apertures 209 (depicted as dotted lines).

Each aperture has at least one edge around its periphery. For example, the rectangular apertures 209 have four edges. In some implementations, in which circular, elliptical, oval, or other curved apertures are formed in the aperture layer 207, each aperture may have only a single edge. In some other implementations, the apertures need not be separated or disjointed in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through the apertures 212 and 209 in the open state, the width or size of the shutter apertures 212 can be designed to be larger than a corresponding width or size of apertures 209 in the aperture layer 207. In order to effectively block light from escaping in the closed state, the light blocking portions of the shutter 206 can be designed to overlap the edges of the apertures 209. FIG. 2B shows an overlap 216, which in some implementations can be predefined, between the edge of light blocking portions in the shutter 206 and one edge of the aperture 209 formed in the aperture layer 207.

The electrostatic actuators 202 and 204 are designed so that their voltage-displacement behavior provides a bi-stable characteristic to the shutter assembly 200. For each of the shutter-open and shutter-close actuators, there exists a range of voltages below the actuation voltage, which if applied while that actuator is in the closed state (with the shutter being either open or closed), will hold the actuator closed and the shutter in position, even after a drive voltage is applied to the opposing actuator. The minimum voltage needed to maintain a shutter's position against such an opposing force is referred to as a maintenance voltage Vₘ.

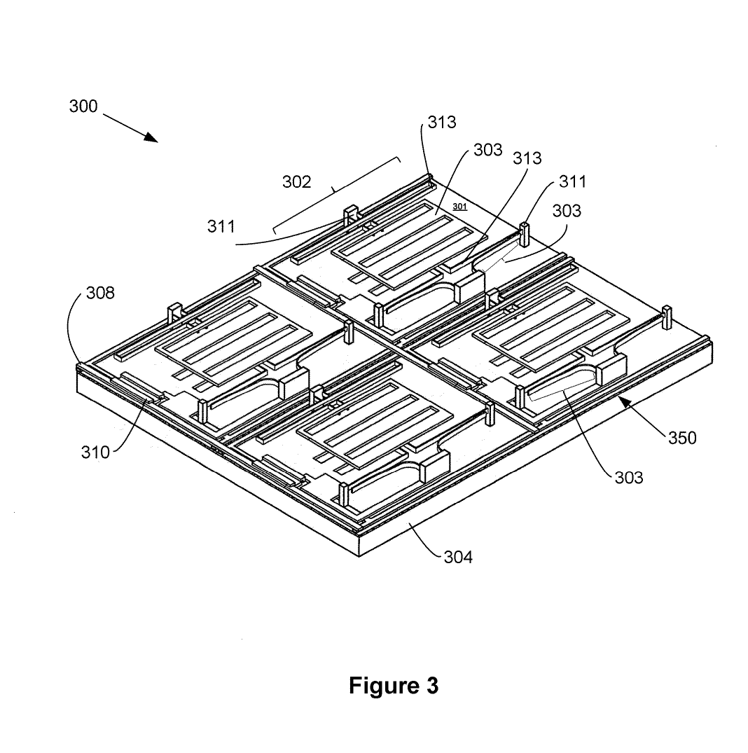

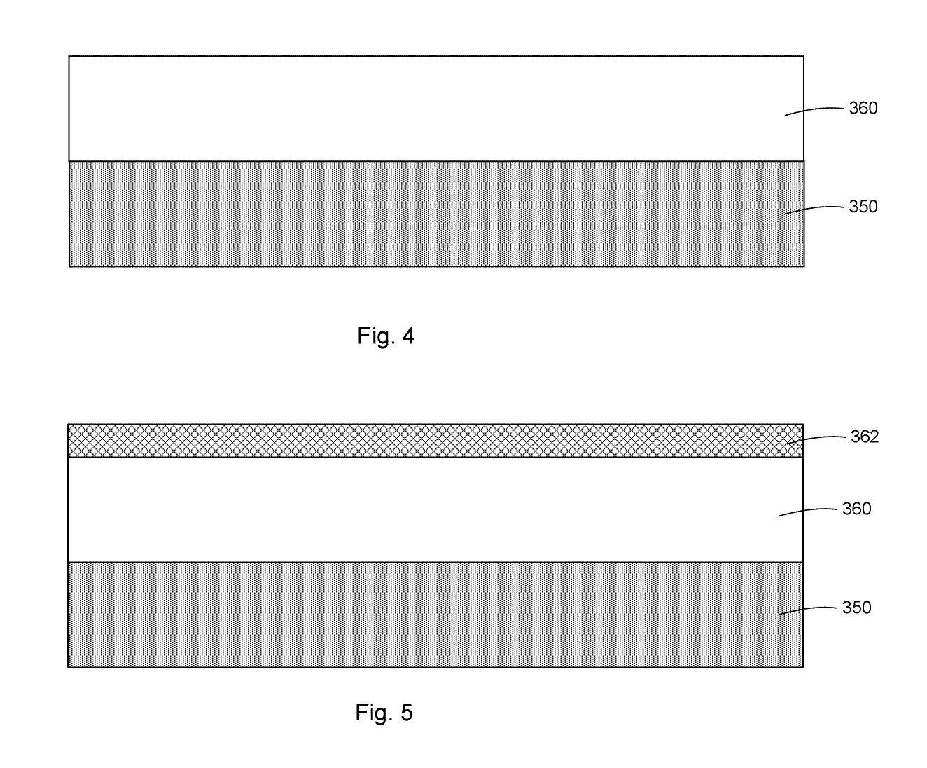

The systems and methods described herein may be employed to form any type of microelectromechancial device, including any device having features with dimensions comparable to the dimensions that are achieved using processes for forming semiconductor devices, such as processes employed for forming patterns of semiconductor material on a surface. A microelectromechancial device can include, without limitations, a light modulator, a microphone, a sensor, piezoresistors, piezoelectric crystals, devices for electromechanical actuation, filters, devices for signal transduction and any other type of component typically employed with semiconductor based electronic devices. For the sake of illustration only, the systems and methods described herein will be discusses with reference to a MEMS shutter assembly for use in a display. FIG. 3 shows an example MEMS shutter assembly formed on a substrate. In particular, FIG. 3 is an isometric view of a portion of an array of shutters 300, where each shutter may provide a pixel within an image of a display. The array of pixels 300 includes four pixels 301 arranged in rows and columns. Each pixel 301 is a semiconductor device fabricated on the surface of a substrate 304. In particular, each pixel 301 is a semiconductor device that has been fabricated as part of an aperture layer 350 that is deposited on the substrate 304. The pixels 301 each include components such as a shutter assembly 302, an actuator 303, apertures 354 and electrical interconnect components, such as the depicted data interconnect 308. The individual components of each pixel 301, such as the actuator 303, or the shutter assembly 302 includes semiconductor components manufactured using a process flow that forms the components as elements carried on the surface of the aperture layer 350. To that end, the aperture layer 350 is deposited and patterned onto the substrate 304. In some implementations, the substrate 304 may be a transparent substrate, such as glass, silica, plastic, or some other material suitable for receiving a layer of semiconductor material that can act as the aperture layer 350 and be processed to form the different components that make up each pixel 301. In one implementation, the aperture layer 350 is deposited and patterned onto the substrate 304. Optionally, a control matrix as described with reference to FIGS. 1A and 1B, may be fabricated on top of the aperture layer 350 and different components such as thin film switches, transistors and capacitors and interconnects, such as the data interconnect 308 may be formed on the aperture layer. The processes employed to fabricate these components can be the typical processes known in the art of manufacturing for active matrix arrays for use in displays, such as liquid crystal displays.

The aperture layer 350 may consist of thin film materials that are process-compatible with the active matrix fabricated on that aperture layer 350. The aperture layer can have holes, such as the holes 354 that may be formed by etching portions of the aperture layer 350 until the substrate 304 is exposed. The processes for fabricating holes, such as the holes 354 can be the same thin film processing techniques used to fabricate the active matrix on the aperture layer 350, and only mask designs or pixel layouts need to be changed to accommodate the formation of aperture holes.

Typically, the aperture layer is deposited as a single thin film onto the substrate 304. Deposition may be accomplished by evaporation, sputtering, chemical vapor deposition, or any suitable technique. The aperture layer 350 may be any suitable semiconductor material, such as amorphous or polycrystalline silicon (Si), geranium (Ge), a gallium arsenide (GaAs) material, or any other suitable material that can be deposited in films having in excess of 500 nm.

FIG. 3 further depicts that the pixels 301 are MEMS devices that include mechanical components that are movable relative to the aperture layer 350. In one process, the components of the pixels 301 are formed using a mold that can support the deposition of semiconductor materials that can be patterned and formed to create the individual components of the pixels 301. For example, molds may be used to create plateaus that will support the deposition of a semiconductor material, such as amorphous silicon. The amorphous silicon may be laid on the plateau as a thin film. The deposited thin film may be hardened and the mold supporting that thin film may be released by any suitable process and to that end may be etched, washed, or otherwise removed to the leave the thin film in place to act as the shutter 303. The shutter 303 is held above the surface of the aperture layer 350. To that end, anchors 311 are formed on the surface of the aperture 350 and extend away from the surface of the aperture layer 350. Sidewall beams 313 connect between the anchors 311 and the shutter 303 to hold the shutter 303 in place and away from the surface of the aperture layer 350. The anchors 311 may attach to the substrate 304 to provide a stable and secure attachment for the components, such as the shutter 303, that are supported by the anchor. In some implementations, the anchors 311 attach to a bare substrate surface and in some implementations the anchors 311 attach to a covered substrate surface, for example, a surface having a layer of diffusion material, passivation material, metallization material or some other material thereon.

To form the anchors 311 and the components of the pixel 301, two layers of resist material are deposited on the surface of the substrate 304 with an intermediate layer of etch stop material. The etch stop material is selected to provide an etch stop sufficient to stop the etching process of at least one etch process. For example, the etch stop may be a titanium (Ti) containing material that is effective against an oxygen based etch chemistry process. The substrate 304 carries a layer of resist material that is positioned intermediate between the substrate 304 and the etch stop layer. A second layer of resist is laid on the etch stop layer. A first etch process may be used to pattern the exposed resist to form a mold pattern suitable for forming the components of the pixel 301 that will be supported by the anchor components, such as the depicted anchors 301. Then an etch chemistry sufficient to remove the etch stop and access the resist material deposited directly over the substrate 304 is applied. This second different etch chemistry may form a mold pattern that extends to the surface of the substrate 304 and provides a mold that may be used to form the anchors, such as the anchors 311 that will support the components of the pixel 301. As with conventional molds, once the mold is in place semiconductor material may be deposited over the mold to form the anchors and the individual components of the pixel 301.

FIG. 4 shows a cross-sectional view of one example of a substrate having a resist coating. In particular, FIG. 4 shows a substrate 350 having a layer of resist 360 deposited across one surface of the substrate. The substrate may be glass, plastic, silica containing materials, single crystal or amorphous Si, other single crystalline material such as quartz or gallium arsenide, or any other substrate suitable for receiving a thin film of deposited material. The resist 360 may be polmethylmethacrylate (PMMA), SU-8, an negative or positive resist, a material that yields aspect ratios suitable for forming sidewalls after photolithography, or any other suitable material that can act as a resist to a photolithographic process. For processes that do not require photo patterned layers, the resist 360 may be replaced with a sacrificial layer and any suitable sacrificial layer may be used that will support a deposited film and will wash, etch or otherwise be removed from the substrate. In some of these implementations,—layer may be a metal, a dielectric or a semi-conductor material. The resist layer 360 is in contact with the substrate 350. The resist layer 360 may be the resist that allows the formation of features used in the mold that will support deposited semiconductor material to form anchors, such as the anchors 311, that support other components of the pixel 301. Optionally, the process may anneal the resist 360 to provide durability and hardness for subsequent process steps.

FIG. 5 depicts one example of a layer of etch stop 362 deposited on the surface of the resist layer 360. The etch stop material may be any suitable etch stop material that is resistant to at least one etch process capable of removing resist material. For example, the etch stop layer 362 may be made of thin layers of metals, such as Ti or Mo, dielectric materials, semiconductor materials, as well as polymides, including hard baked polymides, silicon oxide, silicon carbide, and silicon nitride, or any other material that is resistant to removal from at least one etch process. Additionally, the etch stop material 362 should also act as a sacrificial material for at least one other etch process. As such, the etch stop material 362 is selective in its resistance, and should be able to resist at least one etch process capable of removing resist, and be susceptible to etch by a second different etch process, so that the etch stop 362 may be sacrificed and removed during the formation of the mold. The etch stop material 362 may be deposited by sputtering, chemical vapor deposition, or any other suitable technique and may extend across the entire surface of the resist material 360, or over portions of that surface. How the etch stop material 362 is deposited will depend upon the application, the pattern, and the features being created and this deposition process will include processes known in the art. As noted above, depositing the etch stop, or any material, on a substrate may be achieved by sputtering, Chemical Vapor Deposition (CVD), electrodeposition, epitaxy, thermal oxidation, by physical reaction, Physical Vapor Deposition (PVD), atomic layer deposition, sputtering, casting, or any other technique for chemically or physically moving a material on to the substrate. Deposition may or may not be conformal, depending upon the application and goals of the process operation. The deposited materials may be passivated to prevent problems such as stiction between surfaces. Passivation may be by fluoridation, silanization, hydrogenation, or any suitable process. Typically, the deposited materials are a thin film having a thickness anywhere between a few nanometers to about 100 micrometers.

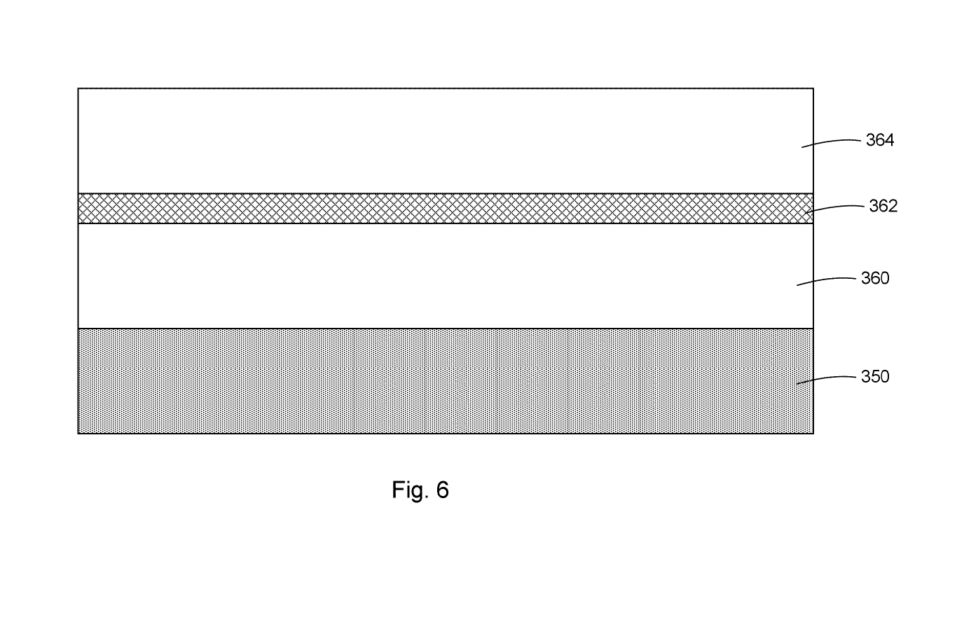

FIG. 6 shows an example of a mold layer applied to the etch stop of FIG. 5. Specifically, FIG. 6 depicts the second layer of resist 364 deposited on the surface of the etch stop material 362 according to one implementation. The resist material 364 can be any suitable resist material and can be the same material used for the resist layer 362. The material can be annealed to be made hard and durable so that it may be patterned to form features of the mold that will be used to form the features of the components of the pixel 301. The thickness of the second resist can determine feature sizes of the components made from the mold patterned out of the second layer of resist. As such, selecting the thickness of the second layer of resist 364 can set a feature size of a component in the microelectromechancial device, such as the height of the shutter 303. Typically, the resist is between about 2 and 5 μm, but other thicknesses may be selected.

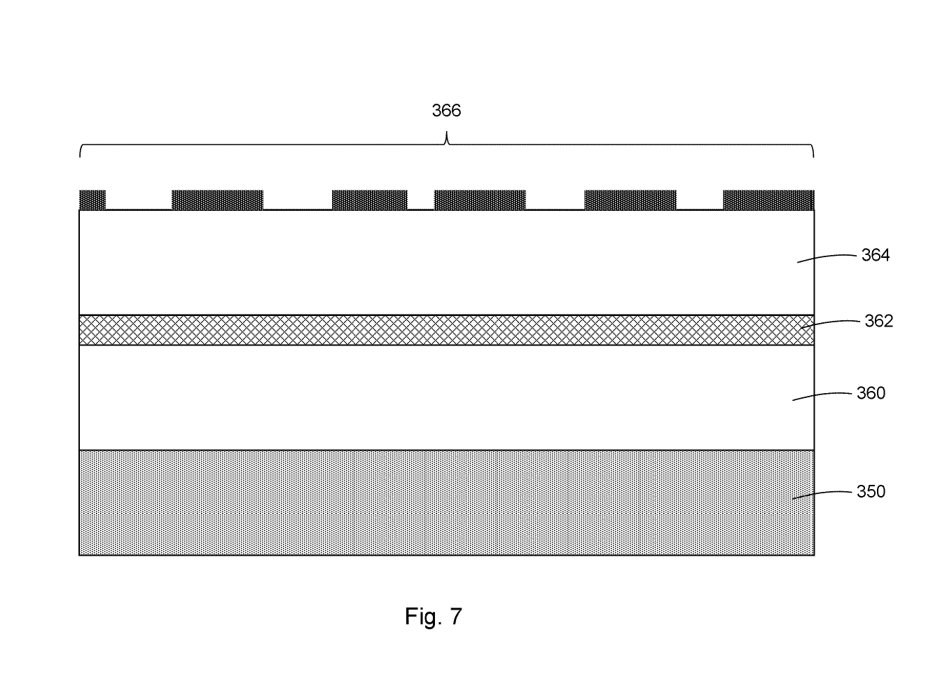

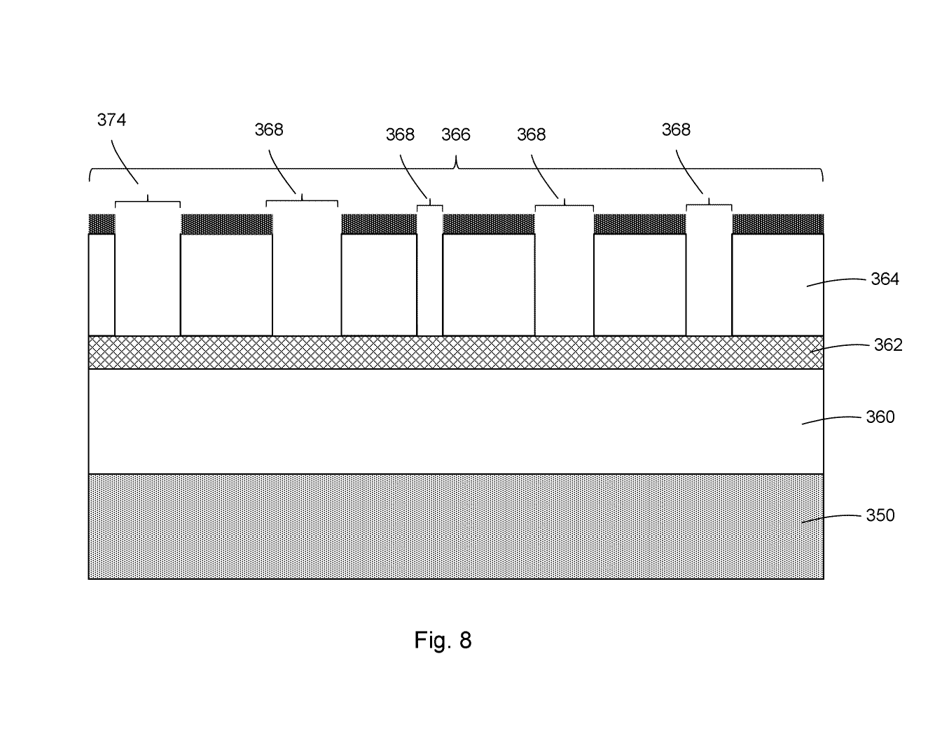

FIG. 7 shows one example of a deposition of a pattern mold. In particular FIG. 7 depicts the deposition of a pattern mold hard mask 366 on the exterior surface of the resist layer 364. The mold hard mask 366 may be any suitable material to form a hard mask and in one implementation may be a layer of molybdenum (Mo) that is deposited by sputtering on the surface of the annealed resist 364. Patterning can take place through any suitable process, such as a chemical wash or a dry etch, or any other suitable technique. In either case, the mold hard mask 366 is patterned to allow subsequent processing of the resist layer 364. FIG. 8 shows an example of a resist etched by an etching process and shows the resist layer 364 being etched to form features of the mold used to form components of the pixel 301 according to one implementation. In one implementation the etch process is an anisotropic etch process that employs an etch chemistry that is ineffective against or substantially ineffective against the material of the etch stop layer 362. As shown in FIG. 8 the resist left exposed by the pattern hard mask layer 366 is removed by the anisotropic etching process and the removal of that resist exposes portions of the etch stop layer 362. The etching process removes portions of the resist layer 364 to form a series of vias 368 and 374. Etch processes may include wet or dry etch processes. Wet etching processes may include any process that employs a solvent, such as potassium hydroxide (KOH), to dissolve material being removed from the substrate. Dry etching may include sputtering away or dissolving using reactive ions or a vapor phase etching. Both wet and dry etching processes may be anisotropic and/or isotropic.

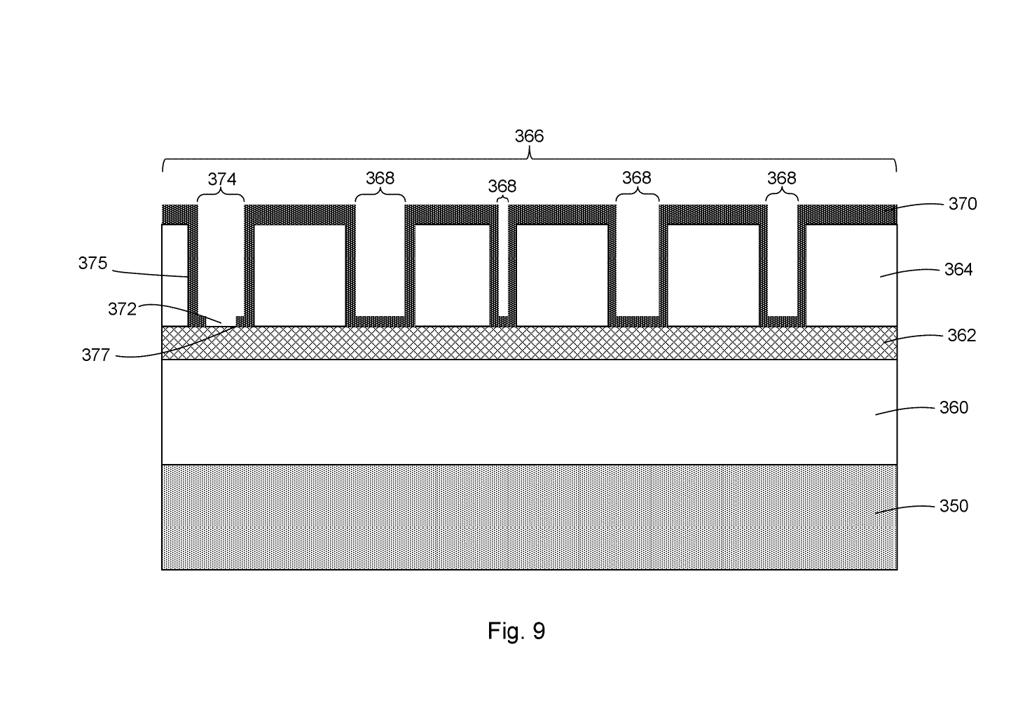

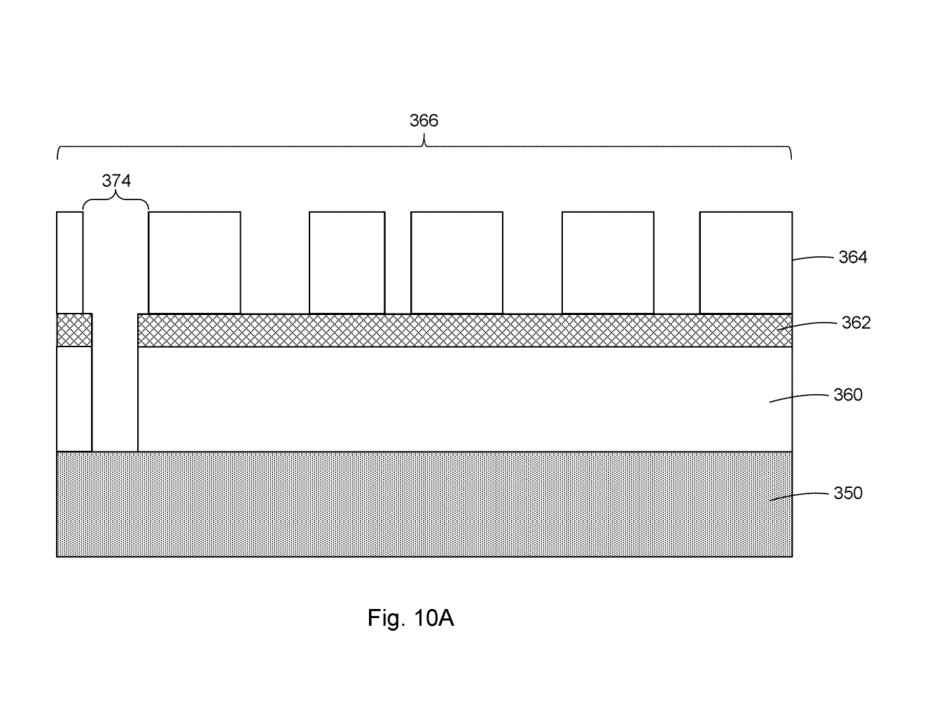

FIG. 9 shows deposition of one example of a hard mask. In particular FIG. 9 shows the deposition of a hard mask 370. The hard mask 370 is a conformal layer of mask material, such as Mo that is deposited using a patterned process to leave portions of the sacrificial layer 362 exposed. For example, the hard mask layer 370 includes an aperture 372 at the bottom of the via 374 that exposes the titanium etch stop layer 362. In some implementations, the aperture 372 may be formed by masking the mold material that was deposited on the aperture so that it is not hardened during a photolithographic step. This unhardened mold material may be etched or washed away in a subsequent operation. In one implementation, the hard mask is a layer of Mo deposited through sputtering to provide conformal deposition of the material. As used herein, the term conformal means having a consistent thickness across features that vary horizontally and vertically over the surface of the resist. Accordingly, the thickness of the hard mask on the sidewalls, such as the sidewalls of the via 374, is substantially the same as the thickness of the mask laid on the bottom wall, such as the bottom wall 377 of the via 374. Once the mask 370 is deposited over the resist layer 364 and portions of the etch stop layer 362, the process can employ an etch process capable of removing the etch stop material. For example, in one implementation, the process may remove a Ti etch stop 362 material that is exposed by aperture 372, and may remove the resist material below the exposed section to etch stop 362. The process include a dry etch and a chlorine based chemistry of for example a gas mixture of chloride or boron trichloride (C12/BC13) or fluorine based chemistry such as tetrafluromethane or sulfur hexafluride (CF4 or SF6). An ion etch process may be employed as well as non-anisotropic processes. In alternative processes, the etch process may be a wet etch process that applies a liquid solvent to remove either the Ti etch stop or the resist. In one implementation the mask layer 370 is resistant to the etch chemistry and the hard mask layer 370 remains intact after the etch process. The process of applying a mask illustrated in FIG. 9 may include using photolithography to apply or form a patterned mask on top of a deposited layer of material, such as resist 364 and etch stop layer 362, by photolithographic imaging. The mask may be used to select areas for removal by the etching processes by altering the characteristics of the patterned layer of material to make that material either more or less susceptible to an etching process.

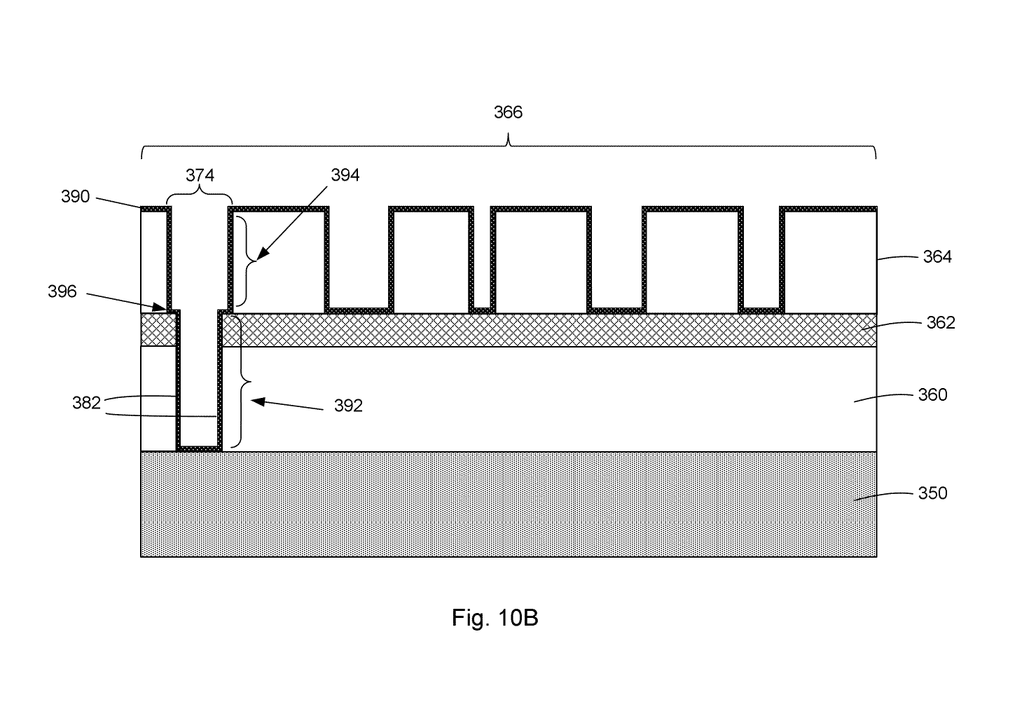

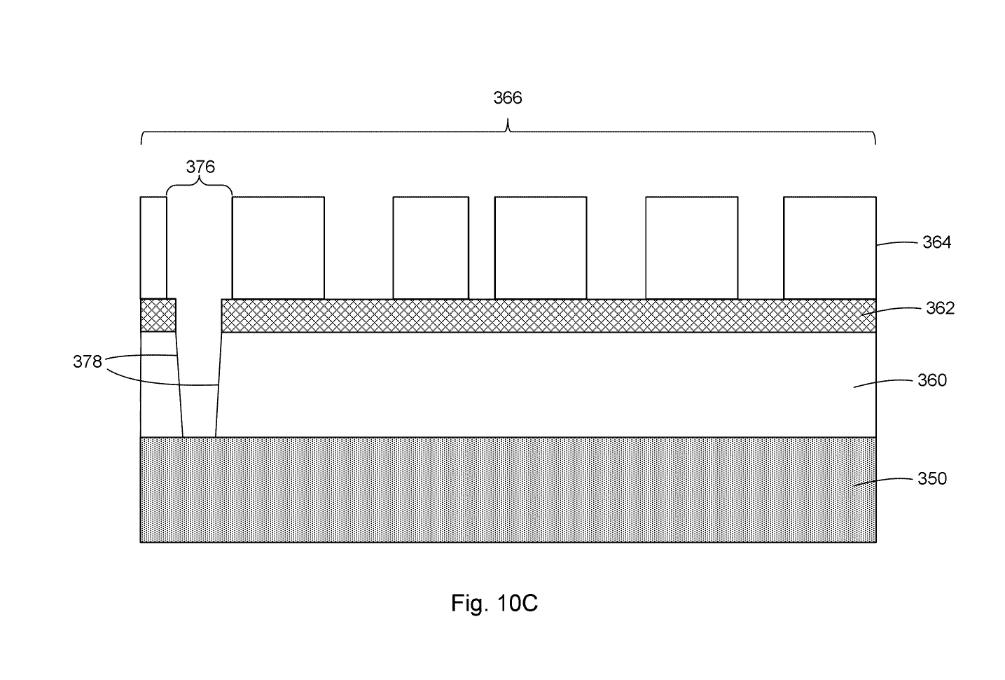

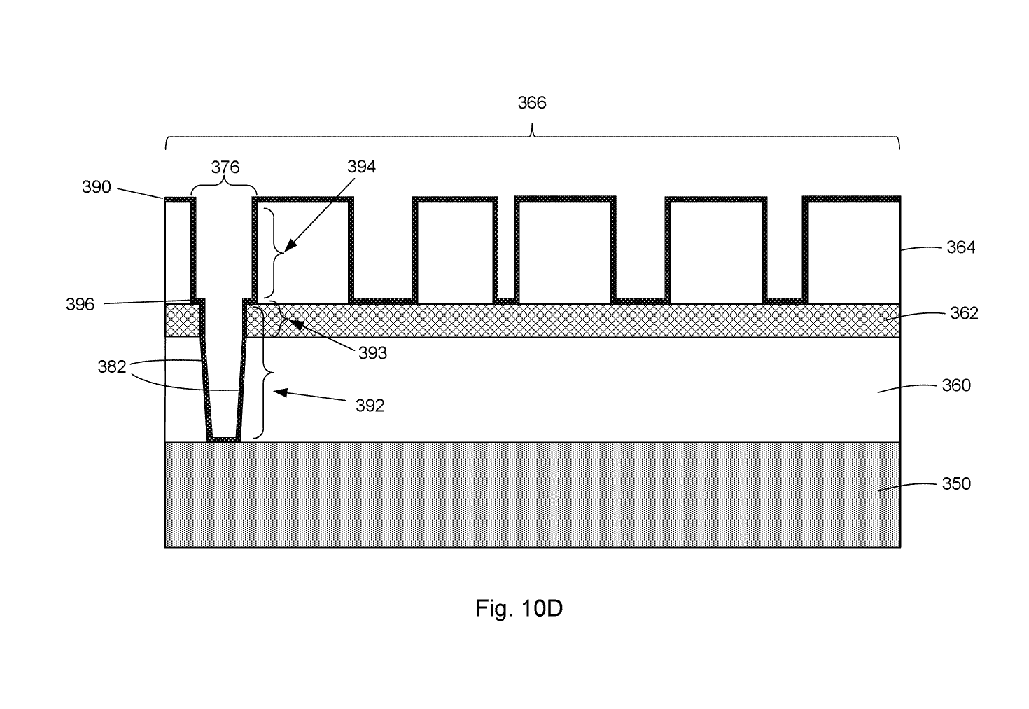

FIGS. 10A and 10B show one example of a via formed through two layers of resist. FIG. 10A further shows the removal of the hard mask layer 370. The removal of the hard mask layer 370 and removal of the etch stop layer 362 underneath the exposed via created by aperture 372 can happen in a single process step, or depending on the process can happen in two separate process steps. FIG. 10A shows that via 374 is extended by the etch process to reach the substrate 350. The via 374 extends through two layers of resist as well as the sacrificial layer and provides a continuous opening from the substrate 350 through to the top of the upper resist layer 364. By using anisotropic etching, the sidewalls of the via 374 as well as the other vias formed in the upper resist layer 364, are essentially perpendicular to the length of the substrate 350. FIG. 10B shows the deposition of material as a conformal layer 390 across the surface of the mold formed by the resist layer 360 and the resist layer 364. In particular, FIG. 10B shows the deposition of a component layer 390. The component layer 390 forms at least some of the components of the pixel 301. The component layer 390 covers the sidewalls and bottom walls of the via 374, and contacts, in this example implementation, the surface of the substrate 350. The component layer 390 forms the sidewalls 382 of an anchor, such as an anchor 311. The sidewalls 382 in this example have a first portion 392 and a second portion 394, and a junction 396 joining the first portion 392 with the second 394 portion. The first portion 392 is in contact with the surface of the substrate 350. In this example, both the first portion 392 and the second portion 394 are substantially orthogonal to the surface of the substrate 350. The junction 396 in this example is a coupling of semiconductor material. The junction 396 joins at one end to the first portion 392 of the sidewall 382. The junction 396 extends, in this example, substantially parallel to the substrate 350. This creates a lateral offset that places the other end of the junction at a location that is laterally spaced away from and offset from the first portion 392 of the sidewall 382. The junction 396 joins to the second portion 394 of the sidewall 382 at a location is that laterally spaced from the first wall.

FIGS. 10C and 10D show a cross-sectional view of another example of a via formed through two layers of resist. FIG. 10C includes a via 376 that extends through resist layer 364, etch stop layer 362 and resist layer 360 to expose a portion of the substrate 350. The via 376 has sidewalls 378 formed in resist layer 360. The sidewalls 378are inclined and at an angle other than 90° relative to the surface of the substrate 350. In some implementations, the sidewalls 378 are formed by a non-anisotropic resist etch process, such as an O₂ only etch process to create a tapered via within resist layer 360 and to achieve the inclined sidewalls 378. FIG. 10D shows a layer 390 of material deposited over the mold created by the etched resist layers 364 and 360. The layer 390 is a component layer that forms at least some of the components of the pixel 301. The component layer 390 covers the sidewalls and bottom walls of the via 376, and contacts, in this example implementation, the surface of the substrate 350. The component layer 390 forms the sidewalls 382 of an anchor, such as an anchor 311. The sidewalls 382 in this example have a first portion 392 that is inclined at an angle other than 90° relative to the surface of the substrate 350, at least for a section of the sidewall 382. In one example, the portion 393 of the sidewall 382 that extends through the etch stop layer 362 is substantially orthogonal to the surface of the substrate 350. In some examples, the first portion 392 is inclined between 2 and 10° off an axis orthogonal to the surface of the substrate 350. The second portion 394 of the sidewall 382 is inclined essentially substantially orthogonally to the surface of the substrate 350 and has a different inclination than at least part of the first portion 392. The sidewall 382 includes a junction 396 joining the first portion 392 with the second 394 portion. The junction 396 in this example is a coupling of semiconductor material. The junction 396 joins at one end to the first portion 392 of the sidewall 382. The junction 396 extends, in this example, substantially parallel to the substrate 350. This creates a lateral offset that places the other end of the junction at a location that is laterally spaced away from and offset from the first portion 392 of the sidewall 382. The junction 396 joins to the second portion 394 of the sidewall 382 at a location is that laterally spaced from the first portion 392.

In an alternate implementation, the resist layer 360 illustrated in FIG. 4 is patterned to form a pattern for an opening. The opening will allow an etch process to etch through the resist layer 360 and form the portion of the via 374 that extends through that resist layer 360. In this implementation, after the hard mask 366 is formed as shown in FIG. 7, an etch process can etch down, such as with an aniostropic etch, to the substrate 350 to form the via 374 and avoid the processes depicted in FIGS. 8 and 9.

In a further alternate implementation, the processes described herein photo-pattern the mold rather than employ an etch process with a hard mask. For example, in some alternate implementations, the resist layer 364 shown in FIG. 10A will be processed using photolithography to photopattern the resist layer 364 to form the mold for the shutter components.

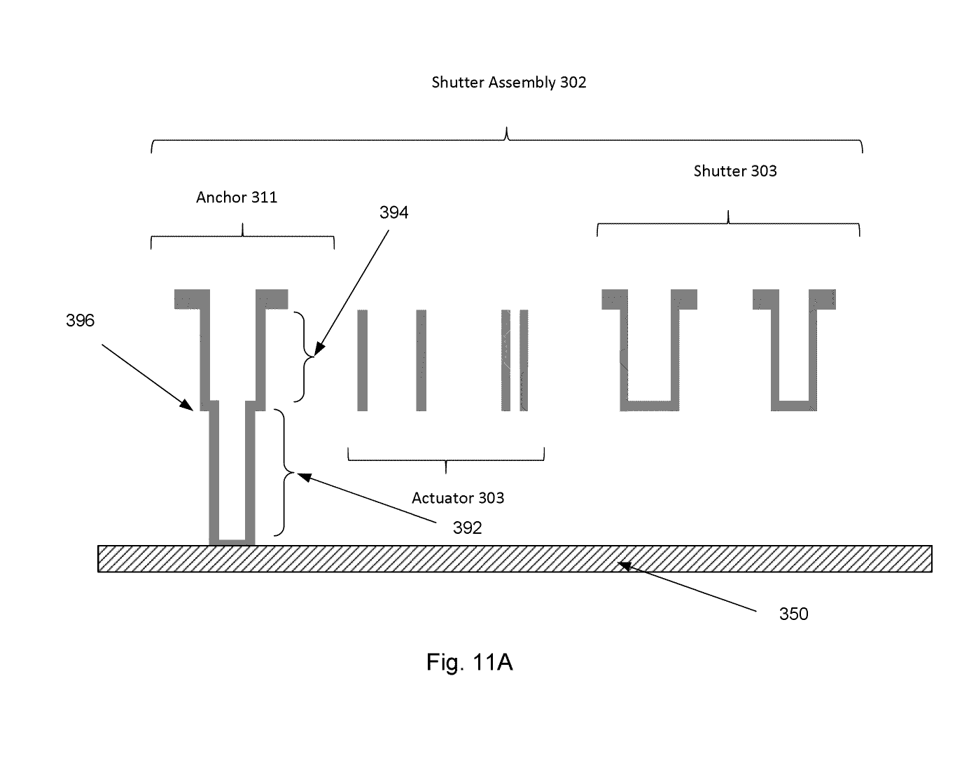

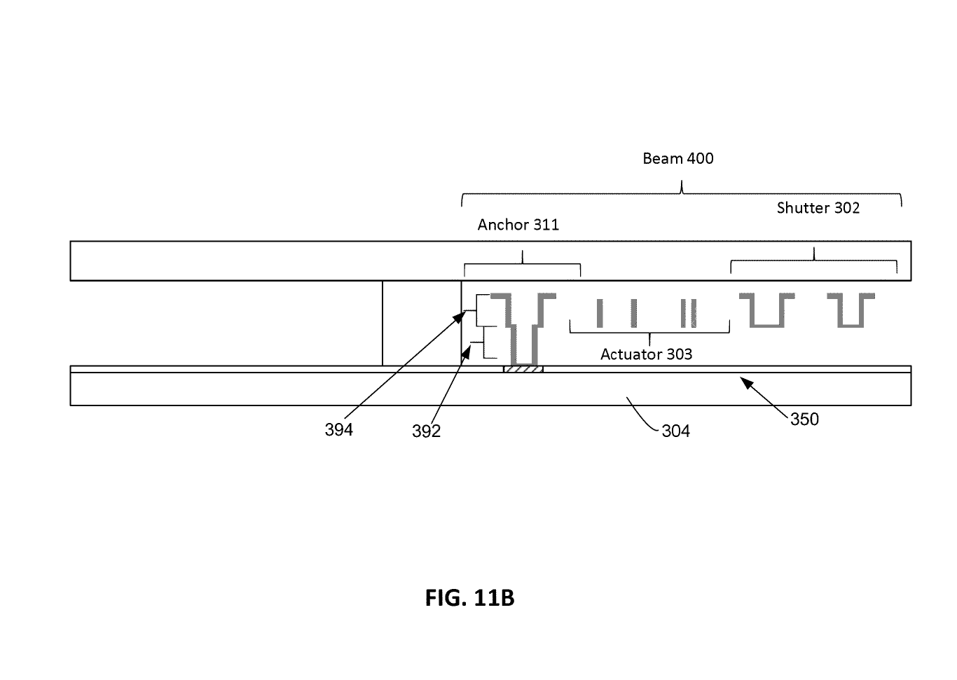

FIG. 11A shows a cross-sectional view of components of a shutter assembly. In particular FIG. 11A shows components of a shutter assembly, such as the shutter assembly 302 depicted with reference to pixel 301 in FIG. 3, and an anchor element 311 that connects to the substrate 350 and extends upward from the substrate 350 to provide sufficient height to hold other components such as the shutter 303 (shown in cross section) above the surface of the substrate 350. The anchor, shutter and actuator are formed by depositing a conformal layer of semiconductor material on the mold depicted in FIGS. 10A or 10B. A release process removes the resist layers 360 and 364 and the etch stop layer 362. The remaining conformal layer, such as the conformal layer 390 in FIGS. 10B and 10D, remains after the resist is removed. For example, FIG. 11A shows that the conformal layer 390 left an anchor 311 having two sidewalls 382 each having a first portion 392 and a second portion 394, and a junction 396 joining the first portion 392 with the second 394 portion. The first portion 392 is in contact with the surface of the substrate 350. In this example, both the first portion 392 and the second portion 394 are substantially orthogonal to the surface of the substrate 350. The conformal layer 390 may be a thin film that may harden through a baking process and the hardened thin film may be released from the mold by etching the mold until only the hardened conformal layer remains. The process for removing the resist material and the etch stop material can be a release process of the type commonly used for forming MEMS devises. In one implementation, the release process delivers CF₄ and O₂ to the mold to remove the resist 360 and 364 and the sacrificial layer 362. Other release processes may be used as appropriate for the application and any suitable release process can be used without departing from the scope of the invention.

FIG. 11B shows a cross-sectional view of the components of a shutter assembly in a display device. In particular FIG. 11B shows the components of a shutter assembly such as the shutter assembly 302 depicted in FIG. 3. The components of the shutter assembly 302 are formed in part by a beam 400 that is connected to the second portion 394 of the sidewall of the anchor 311. The beam 400 in this example extends substantially parallel to the first surface of the substrate 350 and is suspended over the surface of the substrate. The beam 400 can be formed form a conformal layer of semiconductor material, such as the conformal layer 390 depicted in FIG. 10B. The beam 400 can include movable components, like the shutters in the shutter assembly 302 that can move between a first position and a second position to block or modulate light, including light that passes through a substrate 350 made of transparent material. The modulated light can form images for a display. The shutter assembly 302 has an anchor 311 that connects to the substrate 350 and extends upward from the substrate 350 to provide sufficient height to hold other components such as the shutter 303 (shown in cross section) above the surface of the substrate 350. The shutter assembly 302 may be part of an array of display elements, such as the display elements 150 shown in FIG. 1B. The display elements may be covered by a cover plate and controlled by controller 134 to create images on the display.

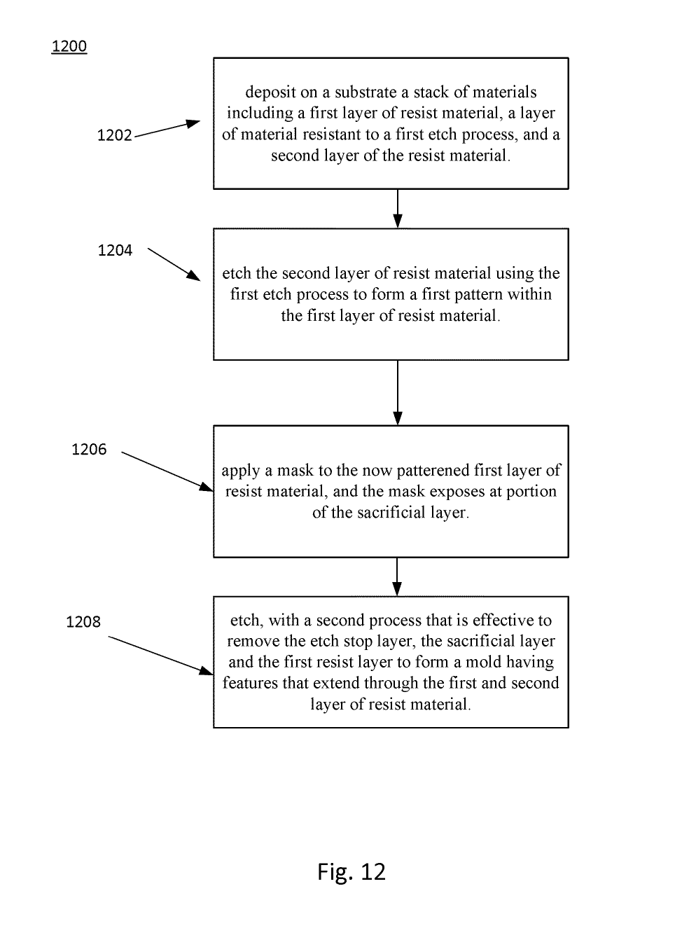

FIG. 12 is a flow chart diagram of one process for forming a MEMS device. FIG. 12 shows a process 1200 for manufacturing a microelectromechancial device. The process 1200 starts at operation 1202 that deposits on a substrate a stack of materials including a first layer of resist material, a layer of material resistant to a first etch process, and a second layer of the resist material. The thickness of each layer may vary according to the application. In one implementation, the operation 1202 deposits layers of resist material that are between 2 and 5 microns in thickness, and a layer of etch stop material that is between about 25 and 125 angstroms. Depositing may be achieved by sputtering, CVD, PVD, or any other technique, including those earlier mentioned, for chemically or physically moving a material on to the substrate. The material resistant to a first etch process can act as an etch stop layer for certain etch processes.

The process proceeds to 1204 and etches the second layer of resist material using the first etch process to form a first pattern within the first layer of resist material. In one implementation, the etch process is an O₂ based anisotropic etch process that does not affect or substantially affect the deposited etch stop layer. The process in step 1206 applies a mask to the now patterned first layer of resist material, and the mask exposes at portion of the sacrificial layer. In 1208, the process 1200 etches, with a second process that is effective to remove the etch stop layer, the sacrificial layer and the first resist layer to form a mold having features that extend through the first and second layer of resist material.

Once etched, the process may optionally deposit a layer of semiconductor material over the etched resist, which provides a mold over which components of a MEMS device may be formed. The process may bake the deposited material and wash away, or otherwise remove the mold, leaving the formed components of the MEMS device.

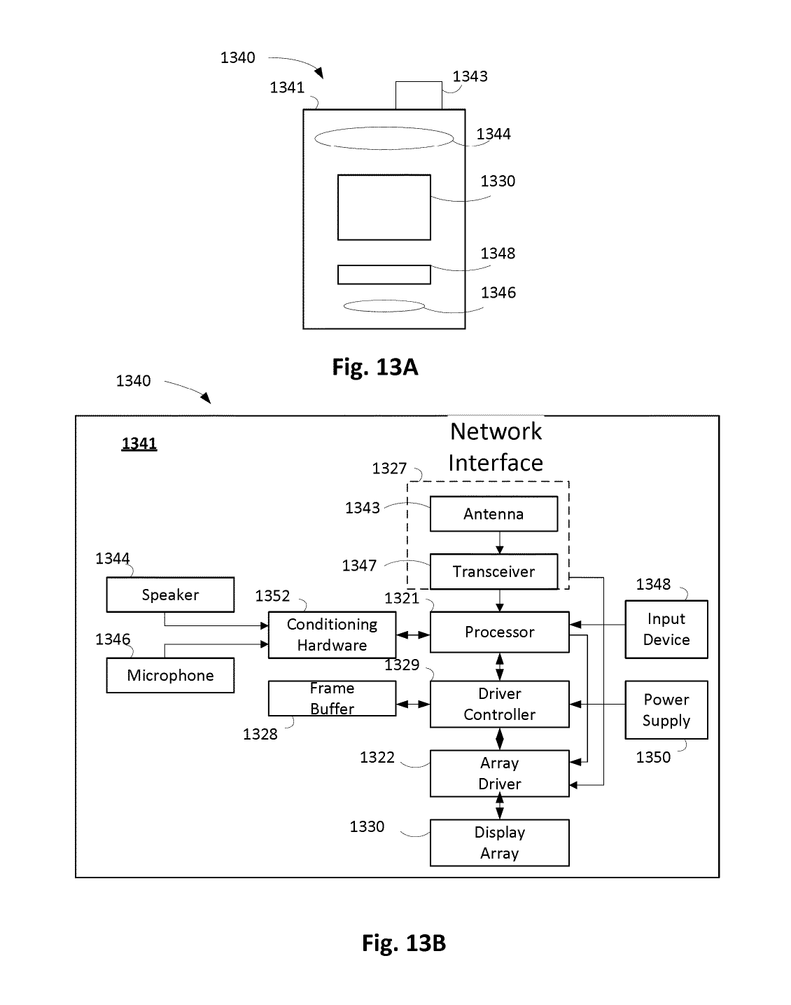

FIGS. 13A and 13B show system block diagrams of an example display device 1340 that includes a plurality of display elements. The display device 1340 can be, for example, a smart phone, a cellular or mobile telephone. However, the same components of the display device 1340 or slight variations thereof are also illustrative of various types of display devices such as televisions, computers, tablets, e-readers, hand-held devices and portable media devices.

The display device 1340 includes a housing 1341, a display 1330, an antenna 1343, a speaker 1345, an input device 1348 and a microphone 1346. The housing 1341 can be formed from any of a variety of manufacturing processes, including injection molding, and vacuum forming. In addition, the housing 1341 may be made from any of a variety of materials, including, but not limited to: plastic, metal, glass, rubber and ceramic, or a combination thereof. The housing 1341 can include removable portions (not shown) that may be interchanged with other removable portions of different color, or containing different logos, pictures, or symbols.

The display 1330 may be any of a variety of displays, including a bi-stable or analog display, as described herein. The display 1330 also can be capable of including a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 1030 can include a mechanical light modulator-based display, as described herein.

The components of the display device 1340 are schematically illustrated in FIG. [13B]. The display device 1340 includes a housing 1341 and can include additional components at least partially enclosed therein. For example, the display device 1340 includes a network interface 1327 that includes an antenna 1343 which can be coupled to a transceiver 1347. The network interface 1327 may be a source for image data that could be displayed on the display device 1340. Accordingly, the network interface 1327 is one example of an image source module, but the processor 1321 and the input device 1348 also may serve as an image source module. The transceiver 1347 is connected to a processor 1321, which is connected to conditioning hardware 1352. The conditioning hardware 1352 may be configured to condition a signal (such as filter or otherwise manipulate a signal). The conditioning hardware 1352 can be connected to a speaker 1345 and a microphone 1346. The processor 1321 also can be connected to an input device 1348 and a driver controller 1329. The driver controller 1329 can be coupled to a frame buffer 1328, and to an array driver 1322, which in turn can be coupled to a display array 1330. One or more elements in the display device 1340, including elements not specifically depicted in FIG. [13A], can be capable of functioning as a memory device and be capable of communicating with the processor 1321. In some implementations, a power supply 1350 can provide power to substantially all components in the particular display device 1340 design.

The network interface 1327 includes the antenna 43 and the transceiver 1347 so that the display device 1340 can communicate with one or more devices over a network. The network interface 1327 also may have some processing capabilities to relieve, for example, data processing requirements of the processor 1321. The antenna 1343 can transmit and receive signals. In some implementations, the antenna 1343 transmits and receives RF signals according to any of the IEEE 16.11 standards, or any of the IEEE 802.11 standards. In some other implementations, the antenna 1343 transmits and receives RF signals according to the Bluetooth® standard. In the case of a cellular telephone, the antenna 1343 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G, or further implementations thereof, technology. The transceiver 1347 can pre-process the signals received from the antenna 1343 so that they may be received by and further manipulated by the processor 1321. The transceiver 1347 also can process signals received from the processor 1321 so that they may be transmitted from the display device 1340 via the antenna 1343.

In some implementations, the transceiver 1347 can be replaced by a receiver. In addition, in some implementations, the network interface 1327 can be replaced by an image source, which can store or generate image data to be sent to the processor 1321. The processor 1321 can control the overall operation of the display device 1340. The processor 1321 receives data, such as compressed image data from the network interface 1327 or an image source, and processes the data into raw image data or into a format that can be readily processed into raw image data. The processor 1321 can send the processed data to the driver controller 1329 or to the frame buffer 1328 for storage. Raw data typically refers to the information that identifies the image characteristics at each location within an image. For example, such image characteristics can include color, saturation and gray-scale level.

The processor 1321 can include a microcontroller, CPU, or logic unit to control operation of the display device 1340. The conditioning hardware 1352 may include amplifiers and filters for transmitting signals to the speaker 1345, and for receiving signals from the microphone 1346. The conditioning hardware 1352 may be discrete components within the display device 1340, or may be incorporated within the processor 1321 or other components.

The driver controller 1329 can take the raw image data generated by the processor 21 either directly from the processor 1321 or from the frame buffer 1328 and can re-format the raw image data appropriately for high speed transmission to the array driver 1322. In some implementations, the driver controller 1329 can re-format the raw image data into a data flow having a raster-like format, such that it has a time order suitable for scanning across the display array 1330. Then the driver controller 1329 sends the formatted information to the array driver 1322. Although a driver controller 1329 is often associated with the system processor 1321 as a stand-alone Integrated Circuit (IC), such controllers may be implemented in many ways. For example, controllers may be embedded in the processor 1321 as hardware, embedded in the processor 1321 as software, or fully integrated in hardware with the array driver 1322.

The array driver 1322 can receive the formatted information from the driver controller 1329 and can re-format the video data into a parallel set of waveforms that are applied many times per second to the hundreds, and sometimes thousands (or more), of leads coming from the display's x-y matrix of display elements. In some implementations, the array driver 1322 and the display array 1330 are a part of a display module. In some implementations, the driver controller 1329, the array driver 1322, and the display array 1330 are a part of the display module.

In some implementations, the driver controller 1329, the array driver 1322, and the display array1330 are appropriate for any of the types of displays described herein. For example, the driver controller 1329 can be a conventional display controller or a bi-stable display controller (such as a mechanical light modulator display element controller). Additionally, the array driver 1322 can be a conventional driver or a bi-stable display driver (such as a mechanical light modulator display element controller). Moreover, the display array 1330 can be a conventional display array or a bi-stable display array (such as a display including an array of mechanical light modulator display elements). In some implementations, the driver controller 1329 can be integrated with the array driver 1322. Such an implementation can be useful in highly integrated systems, for example, mobile phones, portable-electronic devices, watches or small-area displays.

In some implementations, the input device 1348 can be configured to allow, for example, a user to control the operation of the display device 1340. The input device1348 can include a keypad, such as a QWERTY keyboard or a telephone keypad, a button, a switch, a rocker, a touch-sensitive screen, a touch-sensitive screen integrated with the display array 1330, or a pressure- or heat-sensitive membrane. The microphone 1346 can be configured as an input device for the display device 1340. In some implementations, voice commands through the microphone 1346 can be used for controlling operations of the display device 1340. Additionally, in some implementations, voice commands can be used for controlling display parameters and settings.

The power supply 1350 can include a variety of energy storage devices. For example, the power supply 1350 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 1350 also can be a renewable energy source, a capacitor, or a solar cell, including a plastic solar cell or solar-cell paint. The power supply 1350 also can be configured to receive power from a wall outlet.

In some implementations, control programmability resides in the driver controller 1329 which can be located in several places in the electronic display system. In some other implementations, control programmability resides in the array driver 1322. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method for manufacturing a electromechancial system (EMS) device, comprising:
depositing on a substrate, a first layer of sacrificial material, a layer of etch stop material resistant to a first etch process, and a second layer of the sacrificial material,
etching the second layer of sacrificial material using the first etch process to form a first pattern within the second layer of sacrificial material,
applying a mask to the patterned layer of sacrificial material that exposes at least a portion of the etch stop material, and
etching with a second etch process the etch stop material and the first layer of sacrificial material to form a mold having features that extend through the first and second layers of sacrificial material.

2. The method of claim 1, further comprising selecting the thickness of the second layer of sacrificial material to select a feature size of a component in the EMS device.

3. The method of claim 1, wherein depositing the first layer of sacrificial material and the second layer of sacrificial material includes depositing layers of between 1 and 10 μm (microns).

4. The method of claim 1, wherein depositing at least one of the first and second layer of sacrificial material includes depositing a layer of resist material.

5. The method of claim 1, wherein depositing the layer of etch stop material includes depositing a layer of material between about 25 and 5000 Å (angstroms).

6. The method of claim 1, wherein depositing a layer of etch stop material includes depositing a layer of material selected from the group consisting of amorphous silicon, Titanium, silicon oxide, silicon carbide, and silicon nitride.

7. The method of claim 1, wherein applying the mask includes applying a hard mask.

8. The method of claim 7, wherein applying the hard mask includes sputtering a pattern of material selected from the group consisting of metals, silicon dioxide, and geranium.

9. The method of claim 1, wherein etching using the first etch process includes anisotropic etching with oxygen ions.

10. The method of claim 1, wherein etching with the second process includes anisotropic etching with oxygen.

11. The method of claim 1, wherein etching with a first process includes anisotropic etching to form a sidewall substantially perpendicular to the substrate.

12. The method of claim 1, further including depositing a layer of semiconductor material over the etched first and second layers of sacrificial material to form features of the EMS device and removing the first and second layers of sacrificial material and etch stop layer to release the features for use within the EMS device.

13. The method of claim 12, wherein removing the first and second layers of sacrificial material and etch stop layer includes etching with a fluorine compound and oxygen.

14. An electromechanical system (EMS) device, having
a substrate having a first surface,
an anchor attached to the first surface and having a sidewall with a first portion and a second portion, and a junction joining the first portion with the second portion, wherein the first portion is in contact with the first surface of the substrate and the second portion of the sidewall is spaced away from the first surface.

15. The EMS device of claim 14, further comprising
a beam connected to the second portion of the sidewall and extending substantially parallel to the first surface of the substrate.

16. The EMS device of claim 15, wherein the beam includes elements movable between a first position and a second position.

17. The EMS device of claim 14, wherein the substrate includes a transparent material.

18. The EMS device of claim 14, wherein the anchor has a height between 2 and 20 μm (microns).

19. The EMS device of claim 14, wherein the first portion of the sidewall has a first inclination relative to the first surface of the substrate and the second portion of the sidewall has a second, different inclination relative to the first surface of the substrate.

20. The EMS device of claim 14, wherein the first portion of the sidewall and the second portion of the sidewall are inclined substantially orthogonally relative to the first surface of the substrate.

21. The EMS device of claim 14, wherein the anchor includes a second sidewall having a first portion and second portion and a junction joining the first portion with the second portion.

22. The EMS device of claim 14, wherein the junction includes a coupling of semiconductor material having a first end joined to the first portion of the sidewall and a second end being laterally spaced from the first end and joined to the second portion of the sidewall.

23. An apparatus comprising the EMS device of claim 14, wherein the substrate includes a plurality of anchors and a plurality beams having movable elements for modulating light to provide a display,
a processor capable of communicating with the display, the processor being capable of processing image data; and
a memory device capable of communicating with the processor.

24. The apparatus of claim 23, further comprising:
a driver circuit capable of sending at least one signal to the display; and
a controller capable of sending at least a portion of the image data to the driver circuit.

25. The apparatus of claim 23, further comprising:
an image source module capable of sending the image data to the processor, wherein the image source module includes at least one of a receiver, transceiver, and transmitter.

26. The apparatus of claim 23, further comprising:
an input device capable of receiving input data and communicating the input data to the processor.
